(19) United States
(12) Patent Application Publication
(10) Pub. No.: US 2024/0345125 A1
(43) Pub. Date: Oct. 17, 2024

(54) SENSING CIRCUIT OF A MICRO-ELECTROMECHANICAL SENSOR

(71) Applicant: INVENSENSE, INC., San Jose, CA (US)

(72) Inventor: Joseph Seeger, Menlo Park, CA (US)

(21) Appl. No.: 18/753,886

(22) Filed: Jun. 25, 2024

Related U.S. Application Data
(63) Continuation-in-part of application No. 18/500,867, filed on Nov. 2, 2023.
Application No. 18/500,867 is a continuation of application No. 17/894,077, filed on Aug. 23, 2022, now Pat. No. 11,835,538.
Application No. 17/894,077 is a continuation of application No. 16/460,901, filed on Jul. 2, 2019, now Pat. No. 11,428,702.
(60) Provisional application No. 63/567,354, filed on Mar. 19, 2024.
(60) Provisional application No. 62/718,954, filed on Aug. 14, 2018.

(51) Int. Cl. G01P 1/00; G01P 15/00; G01P 15/125; H03F 3/45

(52) U.S. Cl. CPC G01P 1/006; G01P 15/00; G01P 15/125; H03F 3/45; H03F 2200/48; H03F 2203/45156; H03F 2203/45546

(57) ABSTRACT

Applying positive and negative feedback voltages to an electromechanical sensor of a microphone utilizing a voltage-to-voltage converter to facilitate an improvement in sensitivity and reduction in distortion of the microphone is presented herein. A microphone comprises an electromechanical sensor comprising a capacitive sense element comprising a first sense node and a second sense node; and a voltage-to-voltage converter comprising an input, a first output, and a second output. The voltage-to-voltage converter forms, via a first capacitive coupling to the second sense node, a negative feedback loop between the first output of the voltage-to-voltage converter and the input of the voltage-to-voltage converter. The first sense node is electrically coupled to the input of the voltage-to-voltage converter, and the voltage-to-voltage converter forms, via a second capacitive coupling to the first sense node, a positive feedback loop between the second output of the voltage-to-voltage converter and the input of the voltage-to-voltage converter.

### RELATED APPLICATION

This patent application claims priority to U.S. Provisional Patent Application No. 63/567,354, filed on Mar. 19, 2024, and entitled “APPLYING A POSITIVE FEEDBACK VOLTAGE TO AN ELECTROMECHANICAL SENSOR UTILIZING A VOLTAGE-TO-VOLTAGE CONVERTER TO FACILITATE A REDUCTION OF CHARGE FLOW IN SUCH SENSOR REPRESENTING SPRING SOFTENING”, and further claims priority to, and is a continuation-in-part of, U.S. patent application Ser. No. 18/500,867, filed Nov. 2, 2023, and entitled “APPLYING A POSITIVE FEEDBACK VOLTAGE TO AN ELECTROMECHANICAL SENSOR UTILIZING A VOLTAGE-TO-VOLTAGE CONVERTER TO FACILITATE A REDUCTION OF CHARGE FLOW IN SUCH SENSOR REPRESENTING SPRING SOFTENING,” which claims priority to, and is a continuation of, U.S. patent application Ser. No. 17/894,077, filed Aug. 23, 2022, and entitled “APPLYING A POSITIVE FEEDBACK VOLTAGE TO AN ELECTROMECHANICAL SENSOR UTILIZING A VOLTAGE-TO-VOLTAGE CONVERTER TO FACILITATE A REDUCTION OF CHARGE FLOW IN SUCH SENSOR REPRESENTING SPRING SOFTENING,” which claims priority to, and is a continuation of, U.S. patent application Ser. No. 16/460,901 (now U.S. Pat. No. 11,428,702), filed Jul. 2, 2019, and entitled “APPLYING A POSITIVE FEEDBACK VOLTAGE TO AN ELECTROMECHANICAL SENSOR UTILIZING A VOLTAGE-TO-VOLTAGE CONVERTER TO FACILITATE A REDUCTION OF CHARGE FLOW IN SUCH SENSOR REPRESENTING SPRING SOFTENING,” which claims priority to U.S. Provisional Patent Application No. 62/718,954, filed on Aug. 14, 2018, and entitled “GYRO SENSE AMP ARCHITECTURE FOR CANCELLING SPRING SOFTENING EFFECT BY APPLYING CONSTANT CHARGE,” the entirety of which applications are hereby incorporated by reference herein.

### TECHNICAL FIELD

The subject disclosure generally relates to embodiments for applying positive and negative feedback voltages to an electromechanical sensor of a microphone utilizing a voltage-to-voltage (V2V) converter to facilitate an improvement in sensitivity and a reduction in distortion of the microphone.

### BACKGROUND

Conventional microphone technologies are susceptible to distortion due to, e.g., a capacitive load and/or other circuit parasitics electrically coupled to an output of an electromechanical sense element, e.g., capacitive sense element, of a microphone. Further, a sensitivity of the electromechanical sense element with respect to sensing changes in acoustic pressure can vary due to die stress, e.g., caused by variations in assembly of a corresponding device, variations in operating temperature of the corresponding device, variations in operation of the corresponding device over time, or other environmental conditions that can affect a resonant frequency and gain of the electromechanical sense element. In this regard, conventional sensor technologies have had some drawbacks, some of which may be noted with reference to the various embodiments described herein below.

### BRIEF DESCRIPTION OF THE DRAWINGS

Non-limiting embodiments of the subject disclosure are described with reference to the following figures, wherein like reference numerals refer to like parts throughout the various views unless otherwise specified:

FIG. 1 illustrates a block diagram of a portion of a microphone in which positive and negative feedback voltages are applied to an electromechanical sensor of the microphone utilizing a V2V converter to facilitate a reduction in distortion and an improvement in sensitivity of the microphone with respect to sensing changes in acoustic pressure, in accordance with various example embodiments;

FIG. 2 illustrates a block diagram of a portion of a microphone in which positive and negative feedback voltages are applied, via respective capacitive couplings, to an electromechanical sensor of the microphone utilizing a V2V converter to facilitate a reduction in distortion and an improvement in sensitivity of the microphone with respect to sensing changes in acoustic pressure, in accordance with various example embodiments;

FIG. 3 illustrates a block diagram of a negative feedback loop of a portion of a microphone in which positive and negative feedback voltages are applied, via respective capacitive couplings, to an electromechanical sensor of the microphone utilizing a V2V converter to facilitate a reduction in distortion and an improvement in sensitivity of the microphone with respect to sensing changes in acoustic pressure, in accordance with various example embodiments;

FIG. 4 illustrates a block diagram of a positive feedback loop of a portion of a microphone in which positive and negative feedback voltages are applied, via respective capacitive couplings, to an electromechanical sensor of the microphone utilizing a V2V converter to facilitate a reduction in distortion and an improvement in sensitivity of the microphone with respect to sensing changes in acoustic pressure, in accordance with various example embodiments;

FIG. 5 illustrates a block diagram of a portion of a microphone in which respective capacitive couplings of negative and positive feedback paths to an electromechanical sensor of the microphone are modeled by Thevenin equivalent circuits, in accordance with various example embodiments;

FIG. 6 illustrates a block diagram of a portion of a microphone modeled as a differential circuit in which respective capacitive couplings, via a V2V converter, of negative and positive feedback paths to an electromechanical sensor of the microphone are modeled by Thevenin equivalent circuits, and in which respective inputs of amplifiers of the V2V converter include alternating current (AC) noise sources, in accordance with various example embodiments;

FIG. 7 illustrates a Bode plot/diagram representing a frequency response of a negative feedback loop of a portion of a microphone, in which negative feedback voltages of the portion of the microphone are applied, via respective capacitive couplings, to an electromechanical sensor of the microphone utilizing a V2V converter to facilitate a reduction in distortion and an improvement in sensitivity of the microphone with respect to sensing changes in acoustic pressure, in accordance with various example embodiments;

FIG. 8 illustrates a Bode plot/diagram representing a frequency response of a positive feedback loop of a portion of a microphone, in which positive and negative feedback voltages of the portion of the microphone are applied, via respective capacitive couplings, to an electromechanical sensor of the microphone utilizing a V2V converter to facilitate a reduction in distortion and an improvement in sensitivity of the microphone with respect to sensing changes in acoustic pressure, in accordance with various example embodiments;

FIGS. 9 and 10 illustrates block diagrams of a portion of a microphone in which respective capacitive couplings of negative and positive feedback paths to an electromechanical sensor of the microphone are implemented as switching voltage dividers to facilitate modification of a circuit gain of the microphone for varying a sensitivity of the microphone with respect to sensing changes in acoustic pressure, in accordance with various example embodiments;

FIG. 11 illustrates a block diagram of a portion of a microphone in which an electromechanical sensor of the microphone comprises a single-ended output corresponding to a negative feedback loop coupled, via a V2V converter, to the electromechanical sensor to facilitate a reduction in distortion and an improvement in sensitivity of the microphone with respect to sensing changes in acoustic pressure, in accordance with various example embodiments;

FIG. 12 illustrates a block diagram of a portion of a microphone in which positive and negative feedback voltages are applied to an electromechanical sensor of the microphone utilizing a V2V converter, and in which a node of a capacitive sense element of the electromechanical sensor is electrically coupled, via a blocking capacitor, to an input of the V2V converter to facilitate a reduction in distortion and an improvement in sensitivity of the microphone with respect to sensing changes in acoustic pressure, in accordance with various example embodiments;

FIG. 13 illustrates a block diagram of a portion of another microphone in which positive and negative feedback voltages are applied to an electromechanical sensor of the microphone utilizing, via a blocking capacitor, a V2V converter to facilitate a reduction in distortion and an improvement in sensitivity of the microphone with respect to sensing changes in acoustic pressure, in accordance with various example embodiments;

FIG. 14 illustrates a block diagram of a portion of a microphone in which an electromechanical sensor of the microphone comprises a single-ended output corresponding to a negative feedback loop coupled, via a V2V converter, to the electromechanical sensor to facilitate modification of a circuit gain of the microphone for varying a sensitivity of the microphone with respect to sensing changes in acoustic pressure, in accordance with various example embodiments;

FIG. 15 illustrates a block diagram of a portion of another microphone in which an electromechanical sensor of the microphone comprises a single-ended output corresponding to a negative feedback loop coupled, via a V2V converter and blocking capacitor, to the electromechanical sensor to facilitate modification of a circuit gain of the microphone for varying a sensitivity of the microphone with respect to sensing changes in acoustic pressure, in accordance with various example embodiments; and

FIG. 16 illustrates a block diagram of a portion of a microphone in which positive and negative feedback voltages are applied to an electromechanical sensor of the microphone utilizing a V2V converter, in which a node of a capacitive sense element of the electromechanical sensor and the negative feedback loop are electrically coupled to an input of the V2V converter to facilitate a reduction in distortion and an improvement in sensitivity of the microphone with respect to sensing changes in acoustic pressure, and in which a phase lead circuit is included in the negative feedback loop, in accordance with various example embodiments.

### DETAILED DESCRIPTION

Aspects of the subject disclosure will now be described more fully hereinafter with reference to the accompanying drawings in which example embodiments are shown. In the following description, for purposes of explanation, numerous specific details are set forth in order to provide a thorough understanding of the various embodiments. However, the subject disclosure may be embodied in many different forms and should not be construed as limited to the example embodiments set forth herein.

As described above, conventional microphone technologies are susceptible to distortion due to, e.g., a capacitive load and/or other circuit parasitics electrically coupled to an output of an electromechanical sense element of a microphone. Further, a voltage sensitivity to force and pressure that has been applied to a membrane of a sense element of a conventional microphone is limited by a stiffness (e.g., k) of the membrane, and/or by a reduced amount of bias voltage that can be applied to the sense element to affect its sensitivity.

Various embodiments disclosed herein can facilitate an improved sensitivity, a reduced distortion, an improved stability, and/or can prevent overload, or clipping, of a microphone, e.g., a micro-electromechanical systems (MEMS) microphone, by applying positive and negative feedback voltages, via a positive and negative feedback loop, respectively, to an electromechanical sensor of the microphone utilizing a V2V converter.

For example, such embodiment(s) can: utilize, via the negative feedback loop, a phase-lead circuit to improve the stability of the microphone; utilize, via the positive and negative feedback loops, respective gain-switching circuits to modify the sensitivity of the microphone, e.g., to increase the overall sensitivity of the microphone to compensate for a reduced sensitivity of the electromechanical sensor, and/or to prevent the overload, e.g., clipping, of the microphone by decreasing the overall sensitivity of the microphone to compensate for high sound pressure being applied to the electromechanical sensor; and/or present, via the positive feedback loop, a negative capacitive load to the electromechanical sensor to reduce the distortion.

For example, in embodiment(s), a microphone comprises an electromechanical sensor, e.g., a MEMS sensor, and a V2V converter. The electromechanical sensor comprises a capacitive sense element comprising a first capacitive sense element node and a second capacitive sense element node. The V2V converter comprises a V2V converter input, a first V2V converter output, and a second V2V converter output.

The second capacitive sense element node is electrically coupled to the V2V converter input, and the V2V converter forms a negative feedback loop between the first V2V converter output and the V2V converter input. The negative feedback loop is electrically coupled, via a first capacitive coupling, to the first capacitive sense element node.

Further, the V2V converter forms, via an amplifier comprising a gain that is greater than one, a positive feedback loop between the second V2V converter output and the V2V converter input; and the positive feedback loop is electrically coupled, via a second capacitive coupling, to the second capacitive sense element node.

In other embodiment(s), the first capacitive coupling and/or the second capacitive coupling can comprise a capacitive voltage divider, a resistive voltage divider, and/or an amplifier.

In yet other embodiment(s), the output of the electromechanical sensor can comprise a voltage difference between the first V2V converter output and the second V2V converter output, and represent acoustic pressure changes that have been sensed by the capacitive sense element.

In embodiment(s), the positive feedback loop reduces a signal distortion of the output of the electromechanical sensor, e.g., by reducing a load capacitance that is electrically coupled to the capacitive sense element. In other embodiment(s), the positive feedback loop reduces the load capacitance by electrically coupling a negative capacitance to the capacitive sense element. In yet other embodiment(s), to generate a negative capacitance, the positive feedback loop comprises a defined positive loop gain combined with a feedback capacitance of the positive feedback loop.

In other embodiment(s), the negative feedback loop comprises a voltage divider, and modifies, via the voltage divider, a sensitivity of an output of the electromechanical sensor with respect to sensing of acoustic pressure changes that have been sensed by the capacitive sense element—the output comprising a voltage difference between the first V2V converter output and the second V2V converter output. In embodiment(s), the negative feedback loop modifies the sensitivity by modifying a circuit gain of the electromechanical sensor.

In yet other embodiment(s), the first capacitive coupling comprises a first capacitive divider; the second capacitive coupling comprises a second capacitive divider; and a circuit gain of the electromechanical sensor is modified by modifying respective small signal capacitance gains of the first capacitive divider and the second capacitive divider. In an embodiment, the respective small signal capacitance gains are modified by switching respective capacitances of the first capacitive divider and the second capacitive divider to ground.

In other embodiment(s), the microphone further comprises a bias circuit that applies a bias voltage to the first capacitive sense element node, in which the bias voltage sets an operating point of the capacitive sense element to a negative capacitance region.

In yet other embodiment(s), the V2V converter comprises an inverting amplifier and a phase-lead circuit, in which the V2V input is electrically coupled to an inverting amplifier input of the inverting amplifier, and in which the negative feedback loop comprises the inverting amplifier and the phase-lead circuit. In one embodiment, the inverting amplifier comprises the phase-lead circuit.

In embodiment(s), the V2V converter comprises a unity-gain inverting amplifier and a low-pass filter (LPF), and a circuit output corresponding to the phase-lead circuit is electrically coupled to a circuit input corresponding to the unity-gain inverting amplifier. In this regard, the positive feedback loop comprises the inverting amplifier, the phase-lead circuit, the unity-gain inverting amplifier, and the LPF. In an embodiment, the unity-gain inverting amplifier comprises the LPF.

In other embodiment(s), a bias voltage, e.g., +/−5-50 volts, is applied, via a bias resistance (e.g., utilizing a bias circuit), to the second capacitive sense element node, and the second capacitive sense element node is electrically coupled, via a blocking capacitor, to the V2V converter input, e.g., to isolate the V2V converter from being directly connected to the bias voltage.

In yet other embodiment(s), a microphone comprises: an electromechanical sensor comprising a capacitive sense element comprising a first capacitive sense element node and a second capacitive sense element node; and a V2V converter comprising a V2V converter input and a V2V converter output.

The second capacitive sense element node is electrically coupled to the V2V converter input; and the V2V converter forms a negative feedback loop between the V2V converter output and the V2V converter input. The negative feedback loop is electrically coupled, via a capacitive coupling, to the first capacitive sense element node; and the V2V converter output represents acoustic pressure changes that have been sensed by the capacitive sense element.

In embodiment(s), the capacitive coupling comprises a capacitive voltage divider, a resistive voltage divider, and/or an amplifier.

In other embodiment(s), the negative feedback loop comprises a voltage divider, and modifies, via the voltage divider, a sensitivity of the V2V converter output with respect to sensing of the acoustic pressure changes. In an embodiment, the negative feedback loop modifies the sensitivity by modifying a circuit gain of the electromechanical sensor.

In yet other embodiment(s), the microphone further comprises a bias circuit that applies a bias voltage to the first capacitive sense element sense node, and the bias voltage sets an operating point of the capacitive sense element to a negative capacitance region.

In embodiment(s), the V2V converter comprises an inverting amplifier and a phase-lead circuit; the V2V converter input is electrically coupled to an inverting amplifier input of the inverting amplifier; and the negative feedback loop comprises the inverting amplifier and the phase-lead circuit. In one embodiment, the inverting amplifier comprises the phase-lead circuit.

In other embodiment(s), a circuit gain of the electromechanical sensor is modified by modifying a small signal capacitance gain of the capacitive voltage divider. In an embodiment, the small signal capacitance gain is modified by switching capacitances of the capacitive voltage divider to ground.

In yet other embodiment(s), a bias voltage is applied, via a bias resistance, e.g., utilizing a bias circuit, to the second capacitive sense element node, and the V2V converter input is electrically coupled, via a blocking capacitor, to the second capacitive sense element node.

In embodiment(s), a microphone comprises: an electromechanical sensor comprising a capacitive sense element comprising a first capacitive sense element node and a second capacitive sense element node; and a V2V converter comprising a V2V converter input and a V2V converter output.

The second capacitive sense element node is electrically coupled to the V2V converter input; and the V2V converter forms a negative feedback loop between the V2V converter output and the V2V converter input. The negative feedback loop is electrically coupled to the first capacitive sense element node; and the V2V converter output represents acoustic pressure changes that have been sensed by the capacitive sense element.

In other embodiment(s), the V2V converter comprises an inverting amplifier and a phase-lead circuit; the V2V converter input is electrically coupled to an inverting amplifier input of the inverting amplifier; and the negative feedback loop comprises the inverting amplifier and the phase-lead circuit. In one embodiment, the inverting amplifier comprises the phase-lead circuit.

In yet other embodiment(s), a bias voltage is applied, via a bias resistance, e.g., utilizing a bias circuit, to the second capacitive sense element node; and the V2V converter input is electrically coupled, via a blocking capacitor, to the second capacitive sense element node.

In embodiment(s), a microphone comprises an electromechanical sensor comprising a capacitive sense element comprising a first capacitive sense element node and a second capacitive sense element node; a bias resistance that electrically couples a bias voltage to the second capacitive sense element node; and a V2V converter comprising a V2V converter input, a first V2V converter output, and a second V2V converter output.

The second capacitive sense element node is electrically coupled, via a blocking capacitor, to the V2V converter input; and the V2V converter forms a negative feedback loop between the first V2V converter output and the V2V converter input. The negative feedback loop is electrically coupled to the first capacitive sense element node.

The V2V converter forms, via an amplifier comprising a gain that is greater than one, a positive feedback loop between the second V2V converter output and the V2V converter input; and the positive feedback loop is electrically coupled, via a capacitive coupling, to the second capacitive sense element node.

In other embodiment(s), the capacitive coupling comprises a capacitive voltage divider, a resistive voltage divider, and/or an amplifier.

In yet other embodiment(s), an output of the electromechanical sensor comprises a voltage difference between the first V2V converter output and the second V2V converter output and represents acoustic pressure changes that have been sensed by the capacitive sense element.

In embodiment(s), the positive feedback loop reduces a signal distortion of the output of the electromechanical sensor. In an embodiment, the positive feedback loop reduces the signal distortion by reducing a load capacitance that is electrically coupled to the capacitive sense element.

In other embodiment(s), the positive feedback loop reduces the load capacitance by electrically coupling a negative capacitance to the capacitive sense element.

In yet other embodiment(s), the V2V converter comprises an inverting amplifier and a phase-lead circuit; the V2V converter input is electrically coupled to an inverting amplifier input of the inverting amplifier; and the negative feedback loop comprises the inverting amplifier and the phase-lead circuit. In one embodiment, the inverting amplifier comprises the phase-lead circuit.

In embodiment(s), the V2V converter comprises a unity-gain inverting amplifier and a LPF; a circuit output corresponding to the phase-lead circuit is electrically coupled to a circuit input corresponding to the unity-gain inverting amplifier; and the positive feedback loop comprises the unity-gain inverting amplifier and the LPF.

In other embodiment(s), a circuit output corresponding to the phase-lead circuit is electrically coupled to a circuit input corresponding to the unity-gain inverting amplifier. In an embodiment, the unity-gain inverting amplifier comprises the LPF.

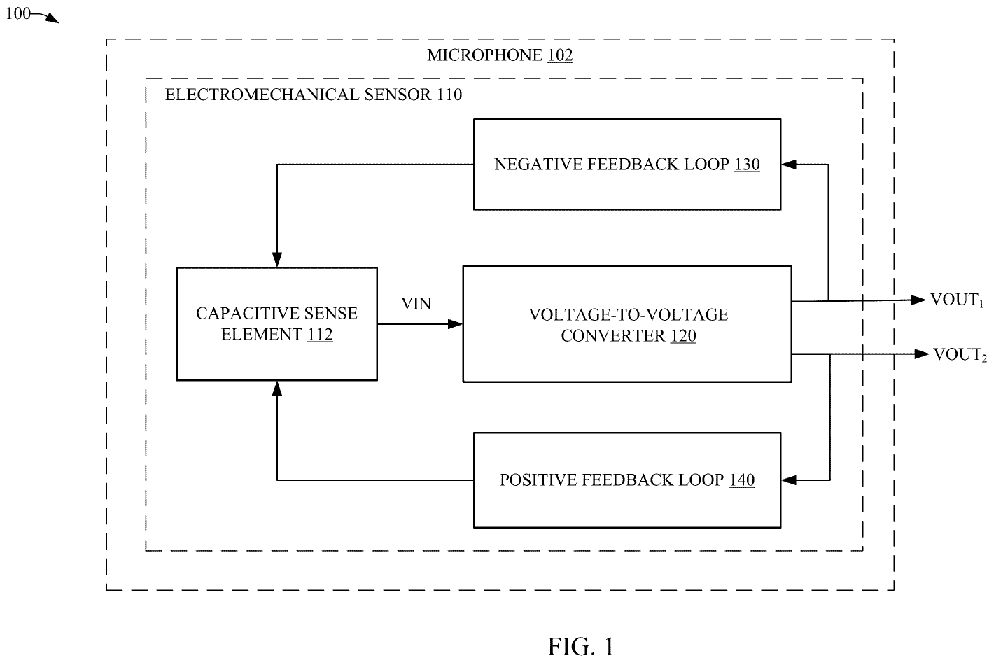

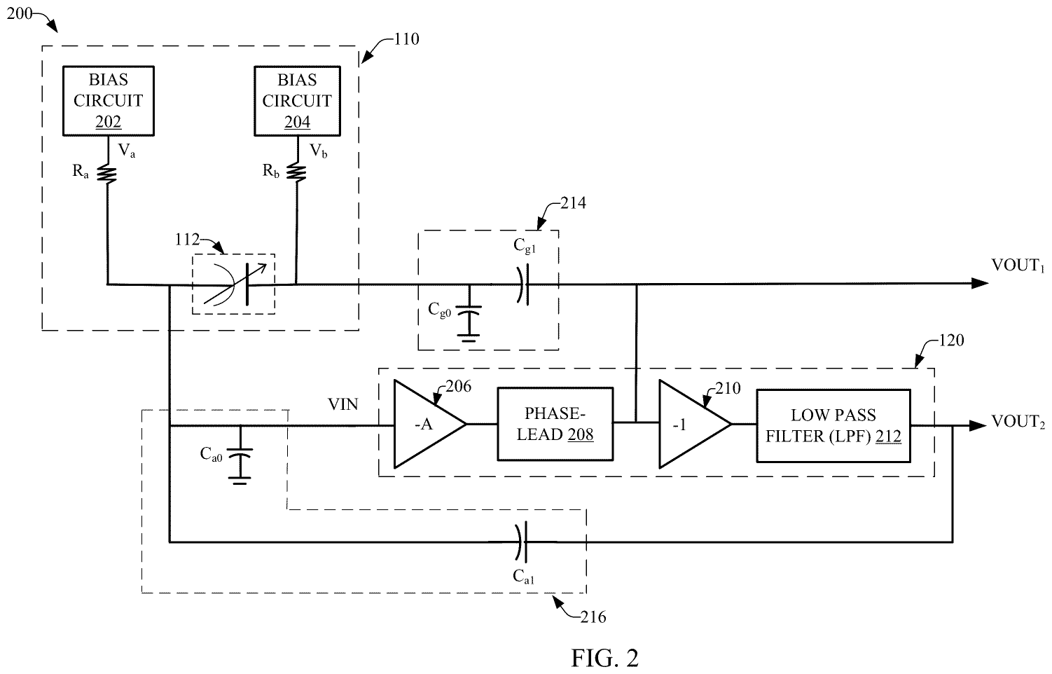

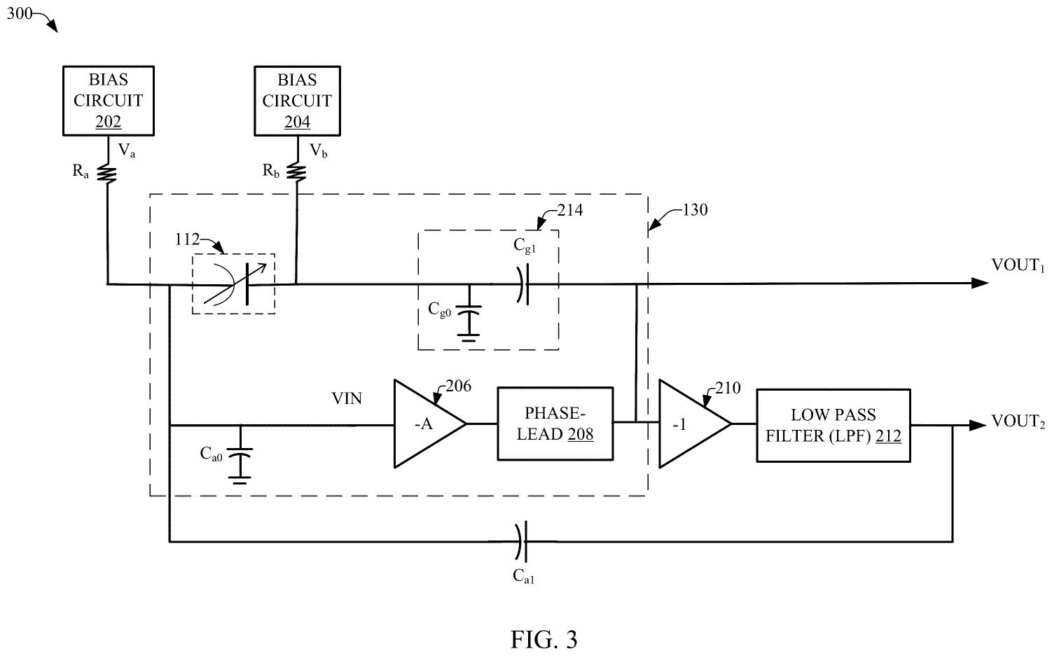

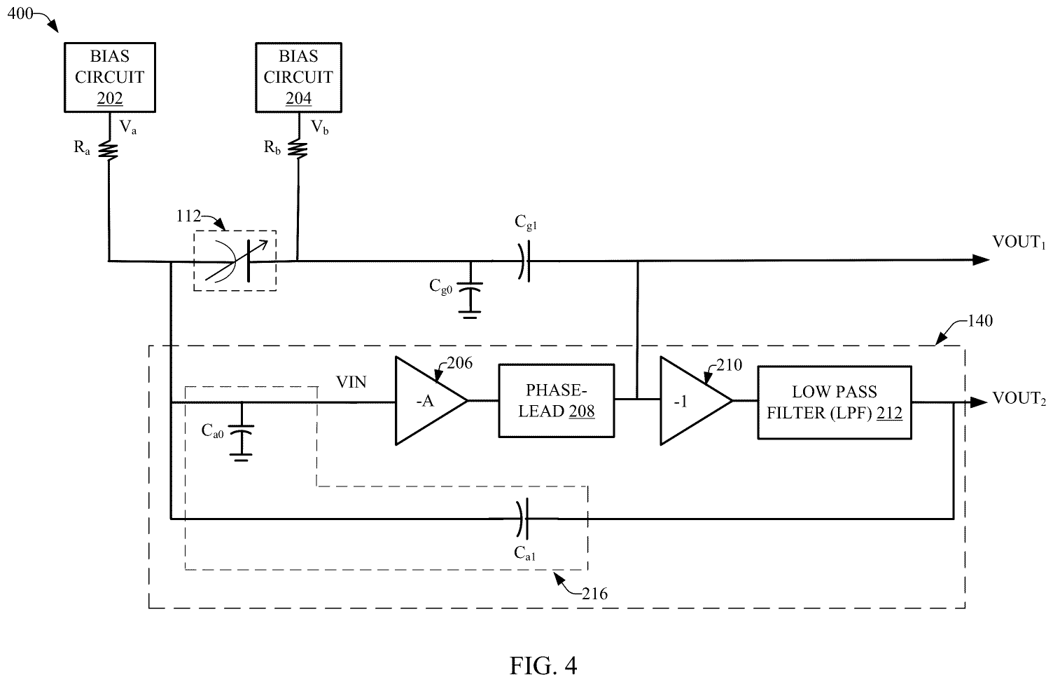

Referring now to FIGS. 1-4, block diagrams (100-400) of a portion of a microphone 102 in which positive and negative feedback voltages are applied to a capacitive sense element (112) of an electromechanical sensor (110) utilizing a V2V converter (120) to facilitate a reduction in distortion and an improvement in sensitivity of the microphone with respect to sensing changes in acoustic pressure are illustrated, in accordance with various example embodiments.

The electromechanical sensor comprises a capacitive sense element (112) comprising a first capacitive sense element node and a second capacitive sense element node. A first bias circuit (202) applies, via a first bias resistor (“Rₐ”) (e.g., a high impedance element (e.g., >1G ohm), a first bias voltage (“Vₐ”) to the second capacitive sense element node. In embodiment(s), Vₐ is ground (0 volts), or a reference voltage that is at a level between standard, e.g., complementary metal-oxide-semiconductor (CMOS), positive (e.g., “V_{dd}”) and negative (e.g., “Vₛₛ”) power supply voltages.

A second bias circuit (204) (e.g., a charge pump) applies, via a second bias resistor (“R_{b}”) (e.g., a high impedance element (e.g., >1G ohm), a second bias voltage (“V”) (e.g., a charge pump generated voltage that is much greater than the first bias voltage, e.g., 5-50 volts) to the first capacitive sense element node—the bias voltages setting an operating point of the capacitive sense element to a negative capacitance region.

In embodiment(s), the second bias circuit can be actively or passively controlled to bias the capacitive sense element to a defined bias point, e.g., corresponding to a target value of charge to be placed on the capacitive sense element.

The V2V converter comprises a V2V converter input (“VIN”), a first V2V converter output (“VOUT₁”), and a second V2V converter output (“VOUT₂”). In embodiment(s), an output of the electromechanical sensor comprises a voltage difference between the first V2V converter output and the second V2V converter output and represents acoustic pressure changes that have been sensed by the capacitive sense element.

The V2V converter input is electrically coupled to the second capacitive sense element node; and the V2V converter forms a negative feedback loop (130) between the first V2V converter output and the V2V converter input. The negative feedback loop is electrically coupled, via a first capacitive coupling (214), to the first capacitive sense element node. In embodiment(s), the first capacitive coupling comprises a capacitive voltage divider (e.g., via “C_{g0}” and “C_{g1}”), a resistive voltage divider (not shown), and/or an amplifier (not shown).

In one embodiment, C_{g0} comprises parasitic capacitors and/or additional capacitors (not shown) that are coupled to the negative feedback loop/first capacitive sense element node.

In another embodiment, C_{g1} provides a negative feedback path, negative feedback voltage, and/or coupling and acts as a blocking capacitor to isolate/separate the higher voltage, biased first capacitive sense element node from the lower voltage nodes, e.g., output(s), of the V2V converter.

The V2V converter further comprises an inverting amplifier (206) (e.g., comprising a negative gain (“−A”)) electrically coupled to a phase-lead circuit (208). In an embodiment (not shown), the inverting amplifier comprises the phase-lead circuit. The V2V converter input is electrically coupled to an inverting amplifier input of the inverting amplifier, and the negative feedback loop comprises the inverting amplifier and the phase-lead circuit.

Further, the V2V converter comprises a unity-gain inverting amplifier (210) and a LPF (212), and a circuit output corresponding to the phase-lead circuit is electrically coupled to a circuit input corresponding to the unity-gain inverting amplifier. In this regard, the V2V converter forms, via an amplifier comprising a gain that is greater than one (e.g., the amplifier comprising the inverting amplifier and the unity-gain inverting amplifier), a positive feedback loop (140) between the second V2V converter output and the V2V converter input. In embodiment(s), the unity-gain inverting amplifier comprises the LPF.

The positive feedback loop is electrically coupled, via a second capacitive coupling (216), to the second capacitive sense element node. In embodiment(s), the second capacitive coupling comprises a capacitive voltage divider (e.g., via “Cₐ₀” and “Cₐ₁”), a resistive voltage divider (not shown), and/or an amplifier (not shown).

In one embodiment, Cₐ₀ comprises an amplifier input capacitance of the inverting amplifier (206), parasitic capacitor(s), and/or additional capacitors (not shown) that are coupled to the positive feedback loop/second capacitive sense element node.

In another embodiment, Cₐ₁ provides a positive feedback path, positive feedback voltage, and/or coupling and acts as a blocking capacitor to isolate/separate the higher voltage, biased first capacitive sense element node from the lower voltage nodes, e.g., output(s), of the V2V converter.

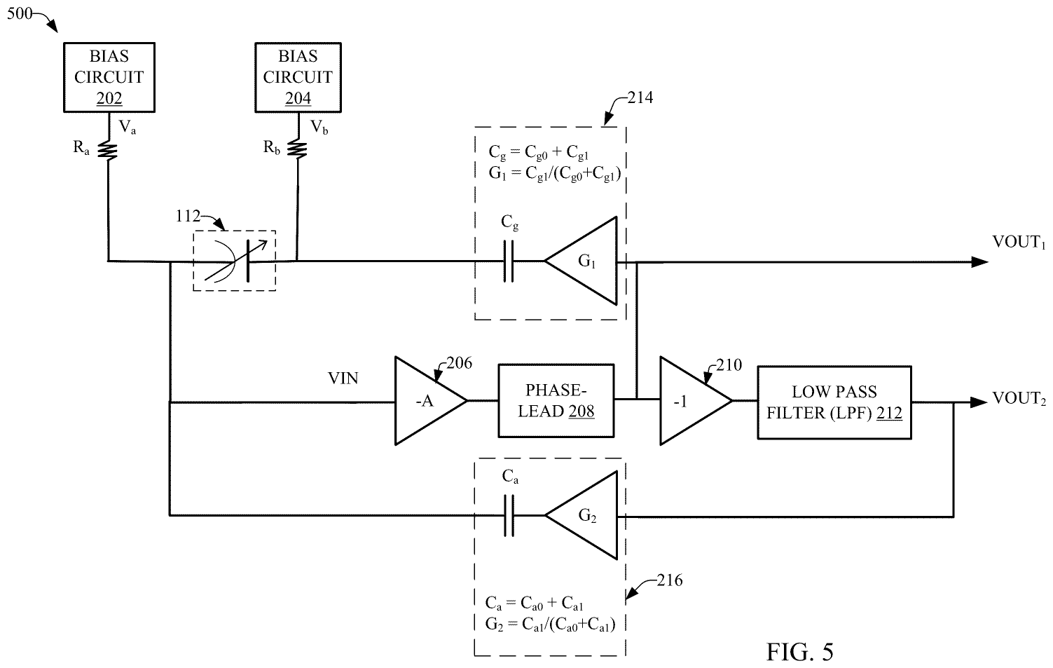

FIG. 5 illustrates a block diagram (500) of a portion (102) of a microphone (not shown) in which respective capacitive couplings (214, 216) of negative and positive feedback paths (130, 140) to an electromechanical sensor (112) of the microphone are modeled by Thevenin equivalent circuits is illustrated, in accordance with various example embodiments. In this regard, the first capacitive coupling (214), e.g., capacitive divider, can be modeled by a Thevenin equivalent circuit comprising a gain stage (“G₁”) electrically coupled, in series, to a capacitor (“C_{g}”) according to the following:

$${C}_{g} = {C}_{g 0} + {C}_{g 1} ,$$

$${G}_{1} = \frac{{C}_{g 1}}{{C}_{g 0} + {C}_{g 1}} .$$

Further, the second capacitive coupling (216), e.g., capacitive divider, can be modeled by a Thevenin equivalent circuit comprising a gain stage (“G₂”) electrically coupled, in series, to a capacitor (“Cₐ”) according to the following:

$${C}_{a} = {C}_{a 0} + {C}_{a 1} ,$$

$${G}_{2} = \frac{{C}_{a 1}}{{C}_{a 0} + {C}_{a 1}} .$$

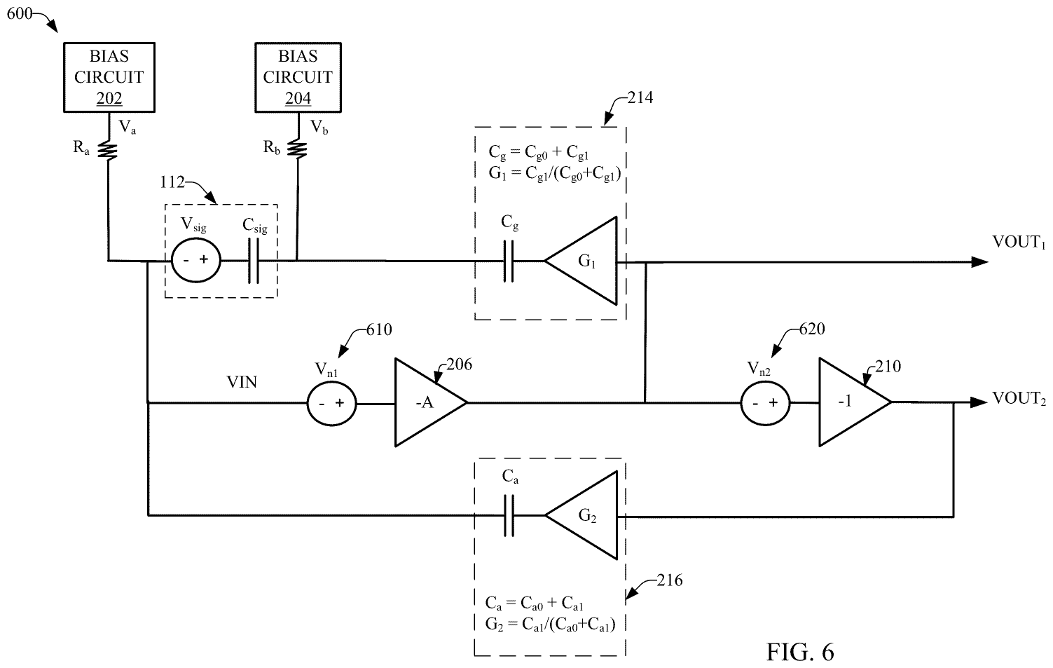

FIGS. 6-9 and the following provide an analysis, (e.g., small-signal analysis) of operation and performance of embodiments described herein with respect to applying positive and negative feedback voltages to an electromechanical sensor of a microphone utilizing a V2V converter to facilitate a reduction in distortion and an improvement in sensitivity of the microphone.

The capacitive sense element (112) is a variable capacitor comprising: a first electrode mechanically coupled to a membrane; and a second electrode forming a capacitor, e.g., MEMS capacitance (C_{MEMS}), with the first electrode, in which the first electrode and the second electrode are separated by a gap, which changes when the membrane and first electrode move in response to forces and pressures being applied to the membrane.

### MEMS Capacitance Operation:

The MEMS capacitance depends on an electrode area (A) and gap (g) as follows:

$${C}_{MEMS} = \frac{ε A}{g} .$$

The gap depends on initial gap (g₀), external force (F, i.e., sound pressure), electrostatic force due to charge (q), and membrane stiffness (k) as follows:

$$g = {g}_{0} - \frac{F}{k} - \frac{1}{2} \frac{{q}^{2}}{ε Ak} .$$

The gap decreases with charge, and the capacitance increases with charge.

The voltage across the MEMS capacitance depends on the charge and the MEMS capacitance as follows:

$$V = \frac{q}{{C}_{MEMS}} = \frac{q}{ε A} ( {g}_{0} - \frac{F}{k} - \frac{1}{2} \frac{{q}^{2}}{ε Ak} ) .$$

The voltage changes due to charge, q.

The voltage changes due to F representing force or sound pressure.

If charge, q, is constant, the voltage change is linear with respect to force (F) change.

### Distortion:

A capacitive load, represented by C₁, can be caused by a capacitive impedance of an electronic circuit coupled to the MEMS capacitance, parasitic capacitance(s), and non-ideal mechanical behavior of the MEMS capacitance such as bending of the first electrode.

The capacitive load on the MEMS capacitance can cause distortion if the total charge (qₜ) on the MEMS capacitance plus the capacitive load on the MEMS capacitance is kept constant.

The charge q on the MEMS capacitance depends on the total charge, the voltage across the MEMS capacitance, and the capacitive load as follows:

$$q = {q}_{t} - {VC}_{l} ,$$

which results in a nonlinear relationship between voltage and force that depends on C₁ as follows (in which the nonlinear relationship leads to distortion):

$$\frac{ε Ak}{( {q}_{t} - {VC}_{l} )} V + \frac{{( {q}_{t} - {VC}_{l} )}^{2}}{2 ε A} = {kg}_{0} - F .$$

### Small-Signal Analysis:

A relationship between charge, voltage, and force of the capacitive sense

$$V = \frac{q}{{C}_{MEMS}} = \frac{q}{ε A} ( {g}_{0} - \frac{F}{k} - \frac{1}{2} \frac{{q}^{2}}{ε Ak} ) .$$

When biased, the electromechanical sensor, and thus the capacitive sense element, typically operates in small perturbations from a bias point. Accordingly, as illustrated by FIG. 6, the capacitive sense element can be represented as a small-signal voltage source and small-signal capacitor as follows:

$${V}_{sig} = \frac{dV}{dF} δ F = - \frac{q}{ε Ak} F ,$$

$${C}_{sig} = {( \frac{dV}{dq} )}^{- 1} = \frac{ε A}{( {g}_{0} - \frac{F}{k} - \frac{3 {q}^{2}}{2 ∈ Ak} )} .$$

Based on the above, respective values of V_{sig} and C_{sig} increase with charge q; and with sufficient charge q, C_{sig} can become negative. In this regard, the negative capacitance comprises a small signal, low-frequency capacitance that is represented by a slope (e.g., negative slope) of a line representing small changes in charge versus small changes in voltage of the capacitive sense element. Operation of the capacitive sense element in the negative capacitance region (i.e., when C_{sig} is negative) is unstable. In embodiment(s), providing active feedback enables stable operation of the capacitive sense element.

Further, V_{sig} sensitivity to a force and a pressure (e.g., sound pressure) that have been applied to a membrane of the capacitive sense element is limited by a stiffness k of the membrane, and/or a bias voltage that has been applied to the capacitive sense element, which can limit charge that can be present on the capacitive sense element. To account for such reduction in V_{sig} sensitivity to force and pressure, embodiments disclosed herein provide a gain boosting circuit configuration to increase and/or modify the V_{sig} sensitivity to force and pressure.

As further illustrated by FIG. 6, the small-signal model of the portion of the microphone includes alternating current (AC) noise sources (610 (“Vₙ₁”), 620 (“Vₙ₂”)); and the phase-lead (208) and the LPF (212) have been removed from the small-signal model because respective gains corresponding to the phase-lead and the LPF are unity in the signal band.

A capacitive load on the capacitive sense element causes distortion in an output signal corresponding to the capacitive sense element. Additional noise is contributed from capacitive load(s) on the capacitive sense element. A load capacitance that is electrically coupled to the capacitive sense element represents a capacitive load from a circuit coupled to the capacitive sense element as:

$${C}_{ℓ} = \frac{1}{\frac{1}{{C}_{g}} + \frac{1}{{C}_{a}} ( \frac{1 + {AG}_{1}}{1 - {AG}_{2}} )} .$$

Due to the positive feedback loop (including “−A”, “−1”, “G₂”, and “Cₐ”), the capacitive load can be ≤0 to meet distortion requirements, if AG₂>1 and Cₐ is sufficiently large.

The differential output due to V_{sig}, Vₙ₁, and Vₙ₂ is:

$${VOUT}_{1} - {VOUT}_{2} = \frac{2 A}{( 1 + {AG}_{1} ) + ( 1 - {AG}_{2} ) ( \frac{{C}_{a}}{{C}_{sig}} + \frac{{C}_{a}}{{C}_{g}} )} ( {V}_{sig} - {V}_{n 1} ( 1 + \frac{{C}_{a}}{{C}_{sig}} + \frac{{C}_{a}}{{C}_{g}} ) + \frac{{V}_{n 2}}{2 A} ( ( 1 + {AG}_{1} ) + ( 1 + {AG}_{2} ) ( \frac{{C}_{a}}{{C}_{sig}} + \frac{{C}_{a}}{{C}_{g}} ) ) ) .$$

Gain Boost: For values of A>1 and for G₁ and G₂ between 0 and 1, the circuit output is boosted relative to V_{sig}.

Regarding noise reduction and cancellation:

For larger values of C_{sig}, the noise contribution from Vₙ₁ and Vₙ₂ is reduced compared to the signal V_{sig}.

If C_{sig} is biased to negative capacitance, such that

$$\frac{1}{{C}_{sig}} = - ( \frac{1}{{C}_{a}} + \frac{1}{{C}_{g}} ) ,$$

amplifier noise Vₙ₁ is cancelled, and the differential output becomes:

$${VOUT}_{1} - {VOUT}_{2} = \frac{2}{{G}_{1} + {G}_{2}} ( {V}_{sig} + \frac{{V}_{n 2}}{2} ( {G}_{1} - {G}_{2} ) ) .$$

If G₁=G₂=G, the inverting amplifier noise Vₙ₂ is also canceled, and the differential output becomes:

$${VOUT}_{1} - {VOUT}_{2} = \frac{1}{G} ( {V}_{sig} ) .$$

In this regard, in embodiment(s), the positive feedback loop reduces a signal distortion of the output of the electromechanical sensor, e.g., by reducing a load capacitance that is electrically coupled to the capacitive sense element, e.g., by electrically coupling a negative capacitance to the capacitive sense element.

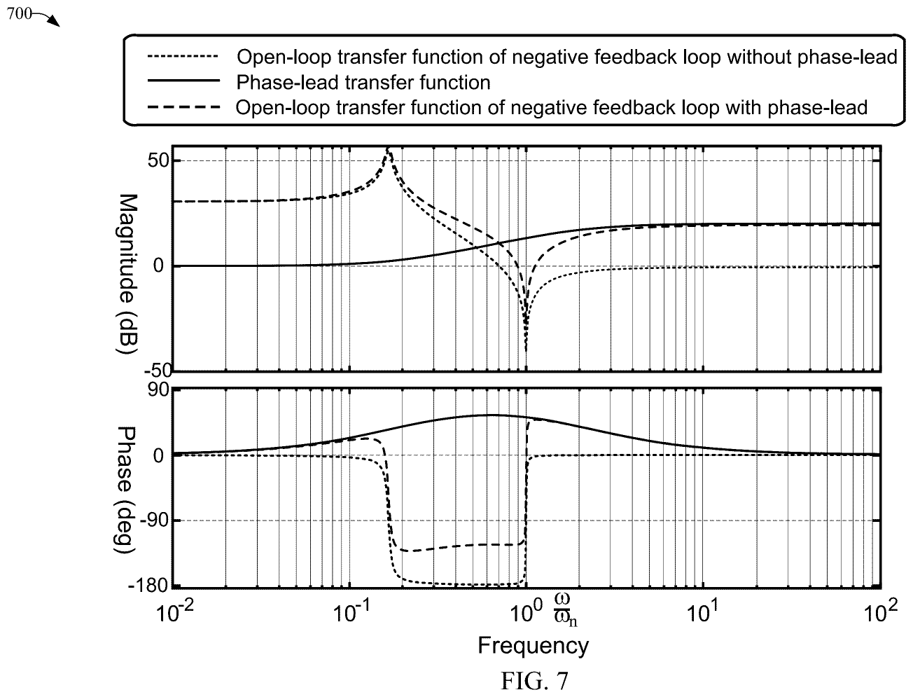

FIG. 7 illustrates a Bode plot/diagram (700) representing a frequency response of the negative feedback loop. The capacitive sense element has a resonant frequency and Q due to a mass, a stiffness(k), and damping of a membrane of the capacitive sense element.

At high frequencies, the membrane doesn't move, and the capacitance of the capacitive sense element only depends on the bias point of the capacitive sense element and is represented as:

$${C}_{HF} = \frac{ϵ A}{( {g}_{0} - \frac{F}{k} \frac{1 {q}^{2}}{2 ϵ Ak} )} .$$

In turn, the small-signal behavior of the capacitive sense element over frequency can be approximated by the following transfer functions:

$${V}_{s} ( s ) = {V}_{sig} \frac{1}{\frac{{s}^{2}}{{ω}_{n}^{2}} + \frac{s}{{ω}_{n} Q} + 1} , {C}_{s} ( s ) = {C}_{HF} \frac{\frac{{s}^{2}}{{ω}_{n}^{2}} + \frac{s}{{ω}_{n} Q} + 1}{\frac{{s}^{2}}{{ω}_{n}^{2}} + \frac{s}{{ω}_{n} Q} + \frac{{C}_{HF}}{{C}_{sig}}} .$$

Phase-lead, or a phase-lead circuit, is required to stabilize the negative feedback loop. A preferred embodiment includes the phase-lead circuit in the inverting amplifier because the additional noise from the phase-lead circuit is added to Vₙ1 and cancelled by C_{sig}.

The negative feedback loop comprises G₁, C_{g}, C_{sig}, the inverting amplifier, and the phase-lead circuit.

An open-loop gain of the negative feedback loop is:

$${G}_{o l 1} = - \frac{{AG}_{1}}{1 + \frac{{C}_{a}}{{C}_{g}} + \frac{{C}_{a}}{{C}_{s} ( s )}} {G}_{p l} ( s ) .$$

The capacitive sense element transfer function is:

$${C}_{s} ( s ) = {C}_{HF} \frac{\frac{{s}^{2}}{{ω}_{n}^{2}} + \frac{s}{{ω}_{n} Q} + 1}{\frac{{s}^{2}}{{ω}_{n}^{2}} + \frac{s}{{ω}_{n} Q} + \frac{{C}_{HF}}{{C}_{sig}}} .$$

The phase-lead transfer function is:

$${G}_{pl} ( s ) = \frac{s {A}_{HF} + p}{s + p} ( max phase at {ω}_{pk} = p \sqrt{{A}_{HF}} and gain = \sqrt{{A}_{HF}} ) .$$

The transfer function of the negative feedback loop has a peak response and a notch.

The notch frequency is the resonant frequency ωₙ of the capacitive sense element.

The open-loop transfer function of the negative feedback loop without the phase-lead has a phase of approximately −180°, which is likely to be closed-loop unstable.

The open-loop transfer function of the negative feedback loop with phase-lead indicates a positive phase margin at the unity gain frequency.

For reasonable values, the unity gain frequency is around 30%-100% of the resonant frequency of the capacitive sense element.

The phase-lead block should be designed to give maximum phase-lead in the range of 20% to 100% of the resonant frequency of the capacitive sense element.

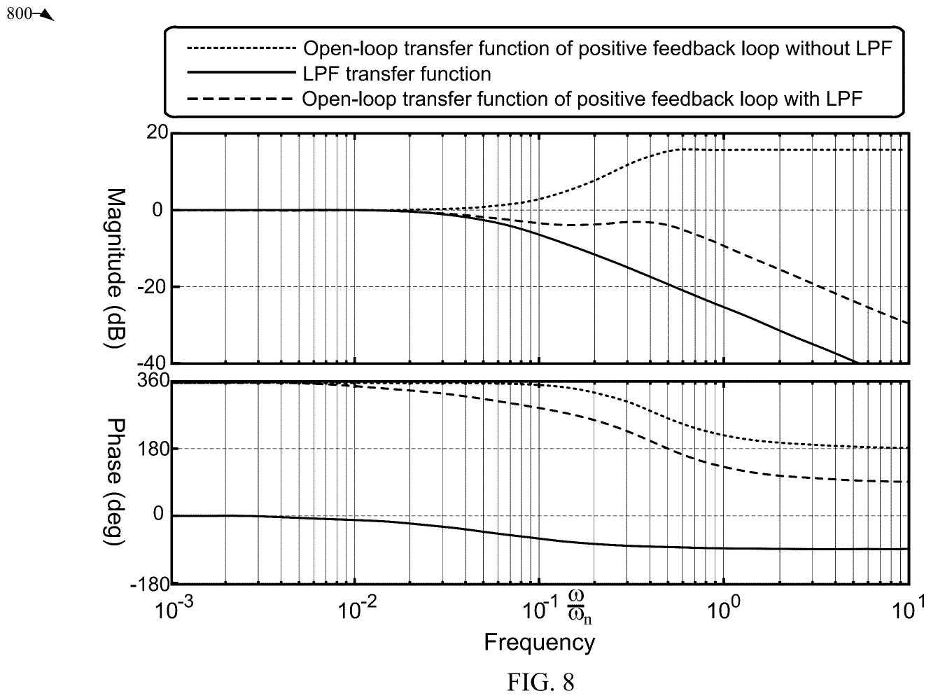

FIG. 8 illustrates a Bode plot/diagram (800) representing a frequency response of the positive feedback loop. A LPF (e.g., LPF circuit) is required to stabilize the positive feedback loop; and a preferred embodiment includes the LPF circuit in the unity-gain inverting amplifier because the additional noise from the LPF circuit is added to Vₙ₂ and cancelled by C_{sig} (e.g., when biasing C_{sig} into a negative capacitance).

The positive feedback loop comprises G₂, Cₐ, the inverting amplifier, the phase-lead, the unity gain inverting amplifier, and the LPF.

An open-loop gain of the positive feedback loop is:

$${G}_{ol 2} = - \frac{{V}_{z}}{{V}_{f}} = \frac{{AG}_{2}}{1 + ( 1 + {AG}_{1} {G}_{pl} ) \frac{( {C}_{s} ‖ {C}_{g} )}{{C}_{a}}} {G}_{lpf} ( s ) .$$

The LPF transfer function is:

$${G}_{lpf} ( s ) = \frac{p}{s + p} .$$

The open-loop transfer function of the positive feedback loop without the LPF has a gain>1 and a phase of approximately −180° at high frequency, which is likely to be closed-loop unstable.

The open-loop transfer function of the positive feedback loop with the LPF indicates a gain<1 at high frequency, meeting stability requirements.

In embodiment(s), a 1^{st} or 2^{nd} order LPF corner frequency can be selected to meet gain-margin requirements, e.g., typical values of the corner frequency will be within approximately 4%-15% of the resonant frequency of the capacitive sense element.

In embodiment(s), in order to have >20 kHz signal bandwidth, the resonant frequency of the capacitive sense element is typically >200 kHz.

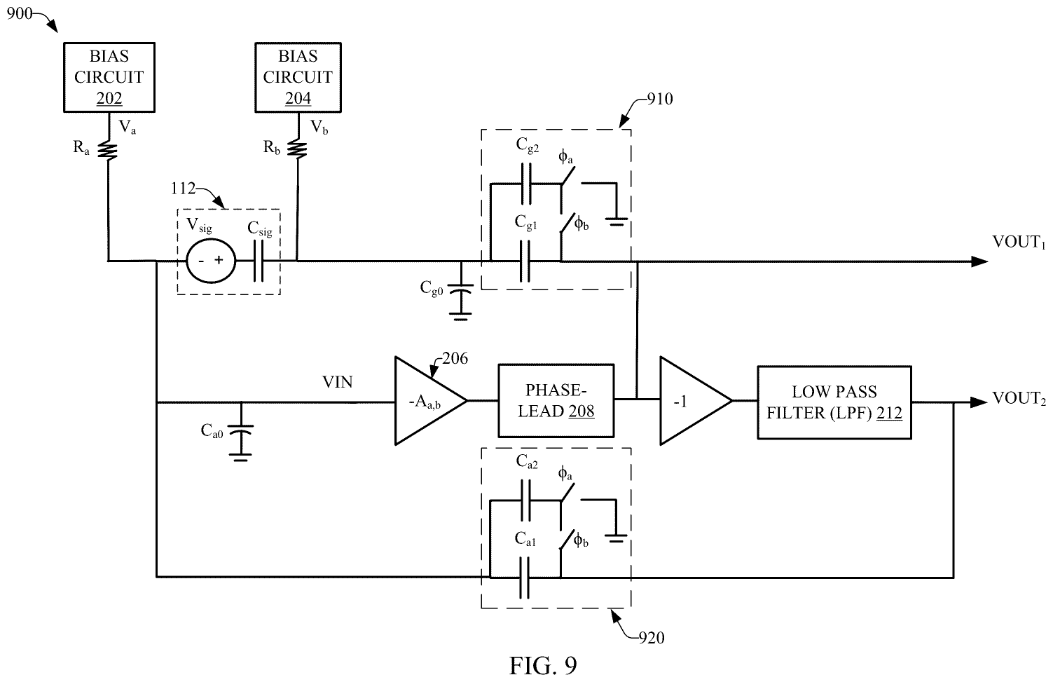

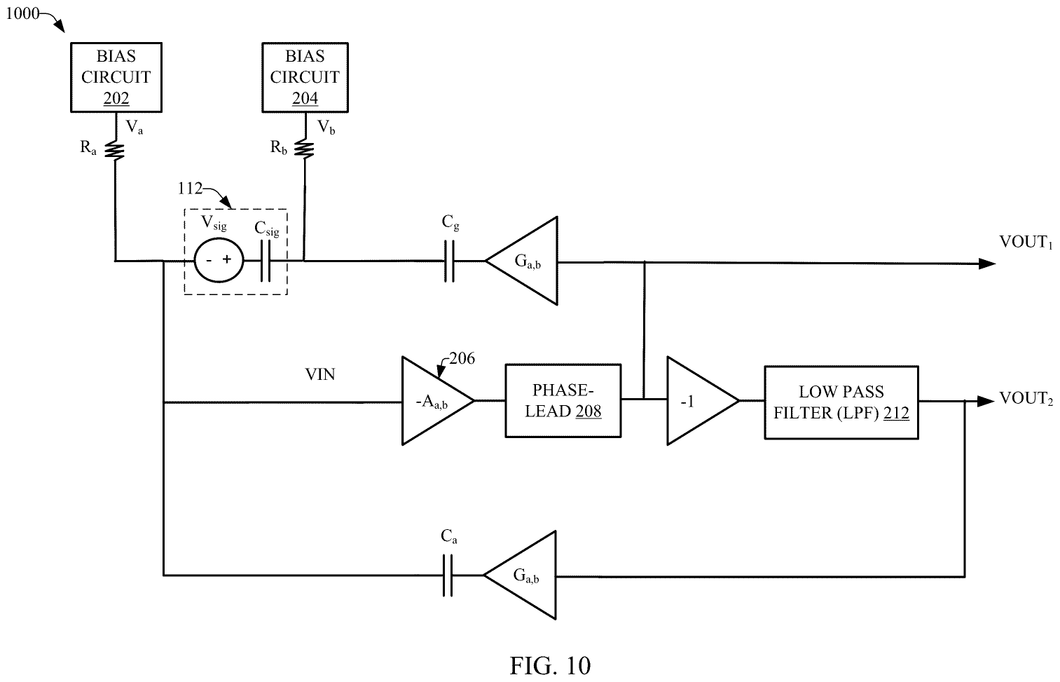

FIGS. 9-10 illustrate block diagrams (900, 1000) of a portion of a microphone in which respective capacitive couplings (910, 920) of negative and positive feedback paths to an electromechanical sensor (e.g., capacitive sense element 112) of the microphone are implemented as switching voltage dividers to facilitate modification of a circuit gain of the microphone, e.g., to vary a sensitivity of the microphone with respect to sensing changes in acoustic pressure.

In embodiment(s), a first capacitive coupling of the negative feedback loop comprises a first capacitive divider formed by C_{g0} and first switched capacitances (910). A second capacitive coupling of the positive feedback loop comprises a second capacitive divider formed Cₐ₀ and second switched capacitances (920). In turn, a circuit gain of the electromechanical sensor can be modified by modifying respective small signal capacitance gains of the first capacitive divider and the second capacitive divider, while maintaining a defined load capacitance of the capacitive sense element, e.g., to reduce signal distortion as described above. In embodiment(s), e.g., as illustrated by FIG. 9, the switched capacitances are controlled via signals ϕₐ and ϕ_{b}, In this regard, when ϕₐ is enabled, ϕ_{b} is open/disabled.

In embodiment(s), the respective small signal capacitance gains of the first and a second capacitive dividers can be modified by switching respective capacitances of the first and second switched capacitances to ground. Gain of switch capacitor 910 can be switched between G₁ₐ and G_{1b}, while gain of switch capacitor 920 can be switch between G₂ₐ and G_{2b}. Such gains can be obtained by switching the respective capacitances of the first and second capacitive dividers based on the following relationships:

When ϕₐ is enabled and ϕ_{b} is disabled, gain Gₐ is equal to the following:

$${G}_{1 a} = \frac{{C}_{g 1}}{{C}_{g 0} + {C}_{g 1} + {C}_{g 2}} \\ {G}_{2 a} = \frac{{C}_{a 1}}{{C}_{a 0} + {C}_{a 1} + {C}_{a 2}} ; and$$

when ϕ_{b} is enabled and ϕ_{b} is disabled, gain G_{b} is equal to the following:

$${G}_{1 b} = \frac{{C}_{g 1} + {C}_{g 2}}{{C}_{g 0} + {C}_{g 1} + {C}_{g 2}} \\ {G}_{2 b} = \frac{{C}_{a 1} + {C}_{a 2}}{{C}_{a 0} + {C}_{a 1} + {C}_{a 2}} .$$

In embodiment(s), a small signal gain/capacitive gain of 910 and a small signal gain/capacitive gain of 920 are not equal. In other embodiments, the small signal gain/capacitive gain of 910 and the small signal gain/capacitive gain of 920 are equal, i.e., G₁ₐ=G₂ₐ=Gₐ and G_{1b}=G_{2b}=G_{b}.

For example, if the capacitive sense element sensitivity is S₀=−74 dbV, at 94 db SPL the following gains can be selected:

$${G}_{a} = \frac{1}{100} \to output sensitivity , {S}_{a} = - 34 dBV , at 94 db SPL , \\ {G}_{b} = \frac{1}{20} \to output sensitivity , {S}_{b} = - 48 dBV . at 94 db SPL .$$

A relationship between a load capacitance of the capacitive sense element and gain A of the inverting amplifier is:

$${C}_{ℓ} = {C}_{pp} + \frac{1}{\frac{1}{{C}_{g}} + \frac{1}{{C}_{a}} ( \frac{1 + AG 1}{1 - AG 2} )} .$$

Load capacitance depends on gain A of the inverting amplifier 206, the small signal gain/capacitive gain (G₁) of 910, and the small signal gain/capacitive gain (G₂) of 920.

Therefore, to obtain the acceptable level of noise/distortion of the microphone, the gain A of the inverting amplifier must be adjusted to keep AG approximately constant, e.g., AG=1.2, as follows:

$${G}_{a} = \frac{1}{100} \to {A}_{a} = 1 \; 20 , {G}_{b} = \frac{1}{20} \to {A}_{b} = 24 .$$

Amplifier gain Aₐ is enabled when the divider gain is Gₐ; Amplifier gain A_{b} is enabled when the divider gain is G_{b}.

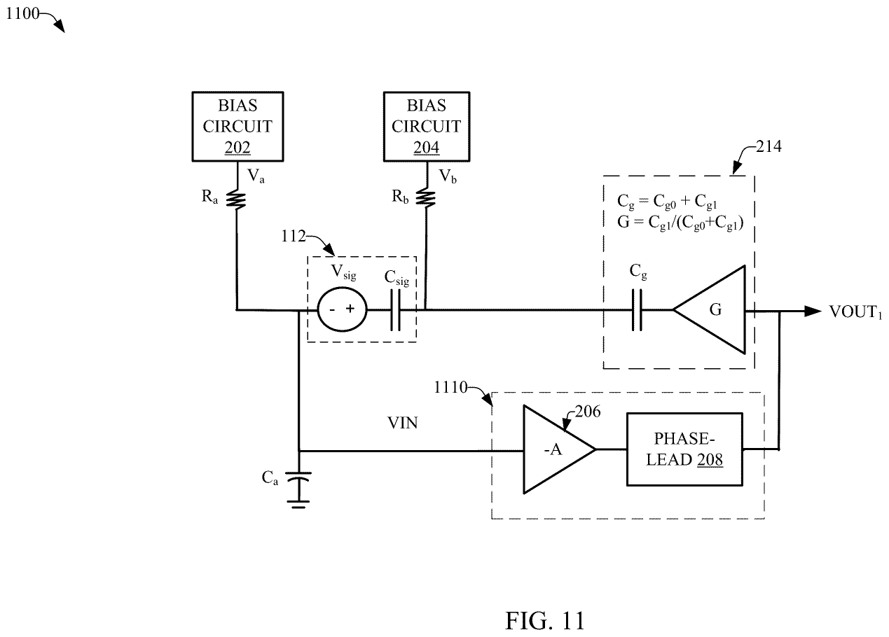

FIG. 11 illustrates a block diagram (1100) of a portion of a microphone in which an electromechanical sensor of the microphone comprises a single-ended output (“VOUT₁”) corresponding to a negative feedback loop that is coupled, via a V2V converter (1110), to the electromechanical sensor to facilitate modification of a circuit gain of the microphone for varying a sensitivity of the microphone with respect to sensing changes in acoustic pressure, in accordance with various example embodiments.

The portion of the microphone comprises an electromechanical sensor comprising a capacitive sense element (112) comprising a first capacitive sense element node and a second capacitive sense element node. The V2V converter comprises a V2V converter input “VIN” and a V2V output (“VOUT₁”).

The V2V converter forms a negative feedback loop between the V2V converter output and the V2V converter input. The negative feedback loop is electrically coupled, via a capacitive coupling (214), to the first capacitive sense element node; and the V2V converter output represents acoustic pressure changes that have been sensed by the capacitive sense element.

In embodiment(s), the capacitive coupling comprises a capacitive voltage divider, a resistive voltage divider, and/or an amplifier.

In other embodiment(s), the negative feedback loop modifies, via the capacitive voltage divider, a sensitivity of the V2V converter output with respect to sensing of the acoustic pressure changes.

In yet other embodiment(s), the negative feedback loop modifies the sensitivity by modifying a circuit gain of the electromechanical sensor.

In embodiment(s), the microphone further comprises a bias circuit (204) that applies a bias voltage (“V_{b}”) to the first capacitive sense element sense node, in which the bias voltage sets an operating point of the capacitive sense element to a negative capacitance region.

The V2V converter comprises an inverting amplifier (206) with gain −A and a phase-lead circuit (208). The V2V converter input is electrically coupled to an inverting amplifier input of the inverting amplifier, and the negative feedback loop comprises the inverting amplifier and the phase-lead circuit. In embodiment(s), the inverting amplifier comprises the phase-lead circuit.

In other embodiment(s), a circuit gain of the electromechanical sensor is modified by modifying a small signal capacitance gain of the capacitive voltage divider. In yet other embodiment(s), the small signal capacitance gain is modified by switching capacitances of the capacitive voltage divider to ground.

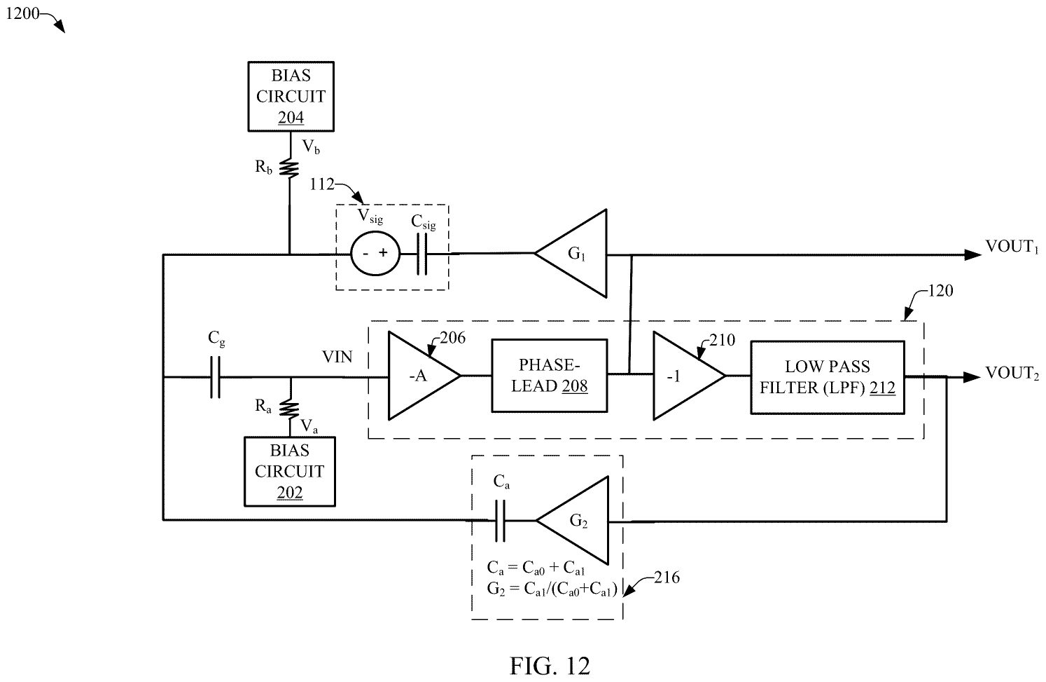

FIG. 12 illustrates a block diagram (1200) of a portion of a microphone in which positive and negative feedback voltages are applied to an electromechanical sensor of the microphone utilizing a V2V converter (120), and in which a node of a capacitive sense element (112) of the electromechanical sensor is electrically coupled, via a blocking capacitor (“C_{g}”), to an input of the V2V converter to facilitate a reduction in distortion and an improvement in sensitivity of the microphone with respect to sensing changes in acoustic pressure, in accordance with various example embodiments.

The V2V converter comprises a V2V converter input (“VIN”), a first V2V converter output (“VOUT₁”), and a second V2V converter output (“VOUT₂”). In embodiment(s), an output of the electromechanical sensor comprises a voltage difference between the first V2V converter output and the second V2V converter output and represents acoustic pressure changes that have been sensed by the capacitive sense element.

A first bias circuit (202) applies, via a first bias resistor (“Rₐ”) (e.g., a high impedance element (e.g., >1G ohm), a first bias voltage (“Vₐ”) to the V2V converter input. In embodiment(s), Vₐ is ground (0 volts), or a reference voltage that is at an approximate mid-point voltage level between standard, e.g., CMOS, positive (e.g., “V_{dd}”) and negative (e.g., “Vₛₛ”) power supply voltages.

The capacitive sense element (112) comprises a first capacitive sense element node and a second capacitive sense element node. A second bias circuit (204) (e.g., a charge pump) applies, via a second bias resistor (“R_{b}”) (e.g., a high impedance element (e.g., >1G ohm), a second bias voltage (“V_{b}”) (e.g., a charge pump generated voltage that is much greater than the first bias voltage, e.g., 5-50 volts) to the second capacitive sense element node—the bias voltages setting an operating point of the capacitive sense element to a negative capacitance region.

The V2V converter forms a negative feedback loop between the first V2V converter output and the V2V converter input; and the negative feedback loop is electrically coupled, via a gain stage (e.g., “G₁”), to the first capacitive sense element node.

In embodiment(s), the gain stage can comprise a capacitive voltage divider, a resistive voltage divider, and/or an amplifier.

The V2V converter forms, via an amplifier comprising a gain that is greater than one (e.g., the amplifier comprising the inverting amplifier and the unity-gain inverting amplifier), a positive feedback loop between the second V2V converter output and the V2V converter input, in which the positive feedback loop is electrically coupled, via a second capacitive coupling (216), to the second capacitive sense element node.

Further, the second capacitive sense element node is electrically coupled, via the blocking capacitor (C_{g}), to the V2V converter input.

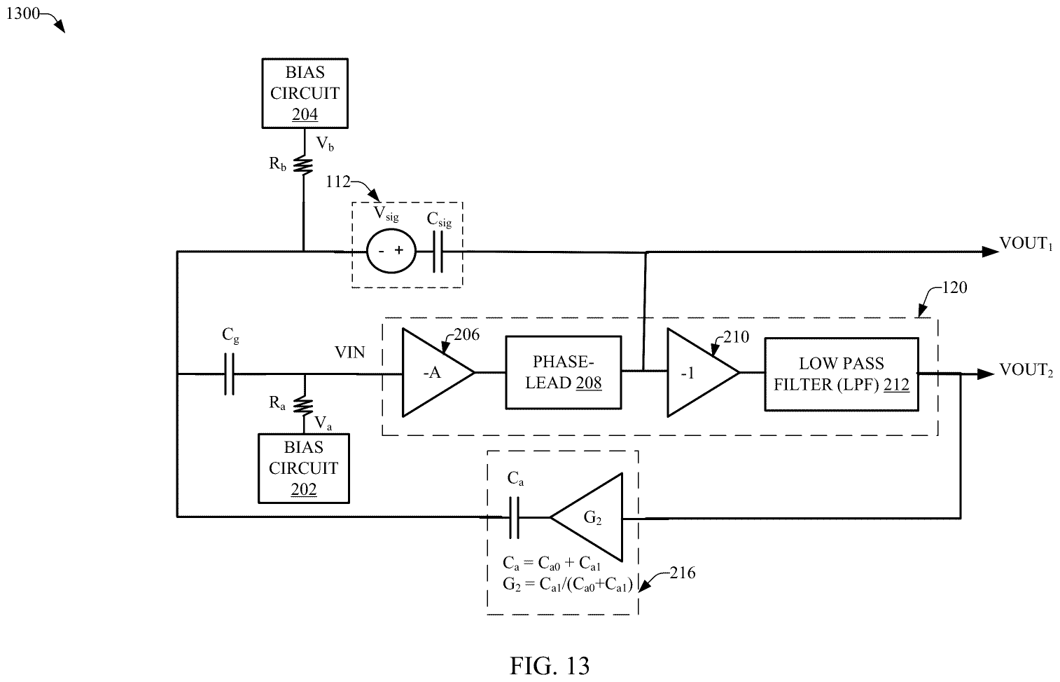

FIG. 13 illustrates a block diagram (1300) of a portion of another microphone in which positive and negative feedback voltages are applied to an electromechanical sensor of the microphone utilizing a V2V converter (120), and in which a node of a capacitive sense element (112) of the electromechanical sensor is electrically coupled, via a blocking capacitor (“C_{g}”), to an input of the V2V converter to facilitate a reduction in distortion and an improvement in sensitivity of the microphone with respect to sensing changes in acoustic pressure, in accordance with various example embodiments.

The V2V converter comprises a V2V converter input (“VIN”), a first V2V converter output (“VOUT₁”), and a second V2V converter output (“VOUT₂”). In embodiment(s), an output of the electromechanical sensor comprises a voltage difference between the first V2V converter output and the second V2V converter output and represents acoustic pressure changes that have been sensed by the capacitive sense element.

A first bias circuit (202) applies, via a first bias resistor (“Rₐ”) (e.g., a high impedance element (e.g., >1G ohm), a first bias voltage (“Vₐ”) to the V2V converter input. In embodiment(s), Vₐ is ground (0 volts), or a reference voltage that is at an approximate mid-point voltage level between standard, e.g., CMOS, positive (e.g., “V_{dd}”) and negative (e.g., “Vₛₛ”) power supply voltages.

The capacitive sense element (112) comprises a first capacitive sense element node and a second capacitive sense element node. A second bias circuit (204) (e.g., a charge pump) applies, via a second bias resistor (“R_{b}”) (e.g., a high impedance element (e.g., >1G ohm), a second bias voltage (“V_{b}”) (e.g., a charge pump generated voltage that is much greater than the first bias voltage, e.g., 5-50 volts) to the second capacitive sense element node—the bias voltages setting an operating point of the capacitive sense element to a negative capacitance region.

The V2V converter forms a negative feedback loop between the first V2V converter output and the V2V converter input; and the negative feedback loop is electrically coupled to the first capacitive sense element node.

The V2V converter forms, via an amplifier comprising a gain that is greater than one (e.g., the amplifier comprising inverting amplifier (206) and unity-gain inverting amplifier (210)), a positive feedback loop between the second V2V converter output and the V2V converter input, in which the positive feedback loop is electrically coupled, via a capacitive coupling (216), to the second capacitive sense element node.

Further, the second capacitive sense element node is electrically coupled, via the blocking capacitor (C_{g}), to the V2V converter input.

In embodiment(s), the capacitive coupling 216 comprises a capacitive voltage divider, a resistive voltage divider, and/or an amplifier.

In other embodiment(s), the positive feedback loop reduces a signal distortion of the output of the electromechanical sensor, e.g., by reducing a load capacitance that is electrically coupled to the capacitive sense element.

In yet other embodiment(s), the positive feedback loop reduces the load capacitance by electrically coupling a negative capacitance to the capacitive sense element.

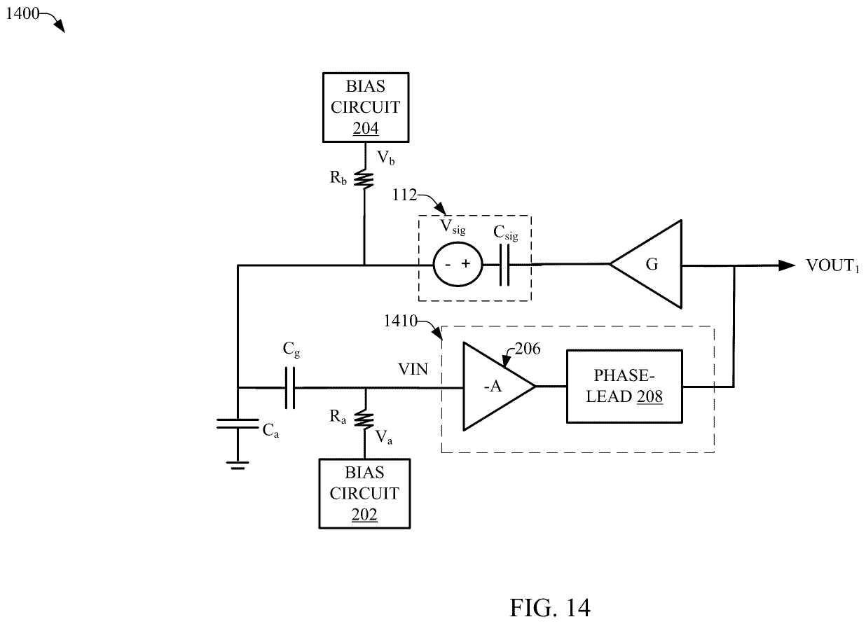

FIG. 14 illustrates a block diagram (1400) of a portion of a microphone in which an electromechanical sensor of the microphone comprises a single-ended output (“VOUT₁”) corresponding to a negative feedback loop coupled, via a V2V converter (1410), to the electromechanical sensor to facilitate modification of a circuit gain of the microphone for varying a sensitivity of the microphone with respect to sensing changes in acoustic pressure, in accordance with various example embodiments.

The V2V converter comprises a V2V converter input (“VIN”) and a V2V converter output (“VOUT₁”). A first bias circuit (202) applies, via a first bias resistor (“Rₐ”) (e.g., a high impedance element (e.g., >1G ohm), a first bias voltage (“Vₐ”) to the V2V converter input. In embodiment(s), Vₐ is ground (0 volts), or a reference voltage that is at an approximate mid-point voltage level between standard, e.g., CMOS, positive (e.g., “V_{dd}”) and negative (e.g., “Vₛₛ”) power supply voltages.

The capacitive sense element (112) comprises a first capacitive sense element node and a second capacitive sense element node. A second bias circuit (204) (e.g., a charge pump) applies, via a second bias resistor (“R_{b}”) (e.g., a high impedance element (e.g., >1G ohm), a second bias voltage (“V”) (e.g., a charge pump generated voltage that is much greater than the first bias voltage, e.g., 5-50 volts) to the second capacitive sense element node—the bias voltages setting an operating point of the capacitive sense element to a negative capacitance region.

The V2V converter forms a negative feedback loop between the first V2V converter output and the V2V converter input; and the negative feedback loop is electrically coupled, via a gain stage (e.g., “G”), to the first capacitive sense element node.

In embodiment(s), the gain stage can comprise a capacitive voltage divider, a resistive voltage divider, and/or an amplifier.

The second capacitive sense element node is electrically coupled, via a blocking capacitor (C_{g}), to the V2V converter input, and is further electrically coupled, via a capacitor (“Cₐ”), to ground.

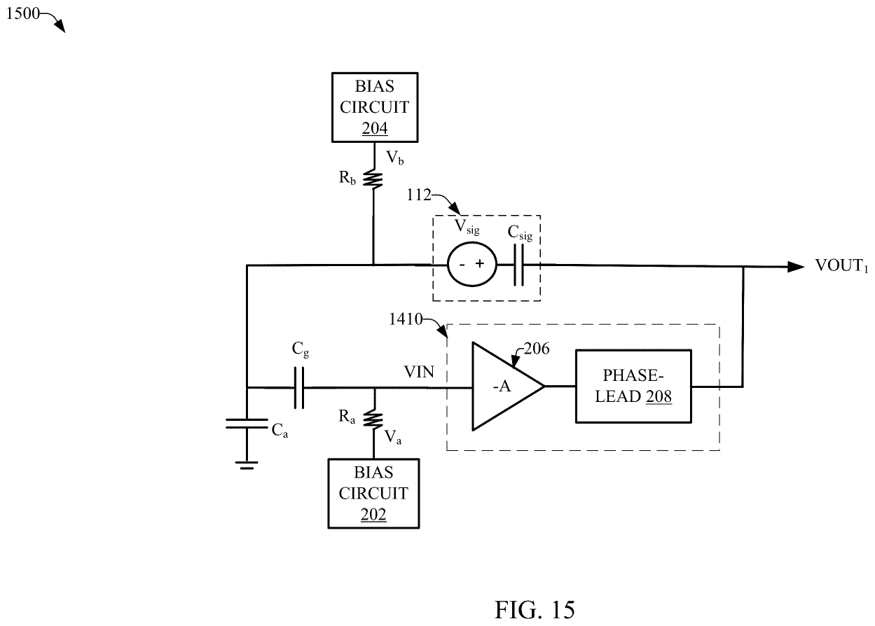

FIG. 15 illustrates a block diagram (1500) of a portion of another microphone in which an electromechanical sensor of the microphone comprises a single-ended output (“VOUT₁”) corresponding to a negative feedback loop coupled, via a V2V converter (1410), to the electromechanical sensor to facilitate modification of a circuit gain of the microphone for varying a sensitivity of the microphone with respect to sensing changes in acoustic pressure, in accordance with various example embodiments.

The V2V converter comprises a V2V converter input (“VIN”) and a V2V converter output (“VOUT₁”). A first bias circuit (202) applies, via a first bias resistor (“Rₐ”) (e.g., a high impedance element (e.g., >1G ohm), a first bias voltage (“Vₐ”) to the V2V converter input. In embodiment(s), Vₐ is ground (0 volts), or a reference voltage that is at an approximate mid-point voltage level between standard, e.g., CMOS, positive (e.g., “V_{dd}”) and negative (e.g., “Vₛₛ”) power supply voltages.

The capacitive sense element (112) comprises a first capacitive sense element node and a second capacitive sense element node. A second bias circuit (204) (e.g., a charge pump) applies, via a second bias resistor (“R_{b}”) (e.g., a high impedance element (e.g., >1G ohm), a second bias voltage (“V”) (e.g., a charge pump generated voltage that is much greater than the first bias voltage, e.g., 5-50 volts) to the second capacitive sense element node—the bias voltages setting an operating point of the capacitive sense element to a negative capacitance region.

The V2V converter forms a negative feedback loop between the first V2V converter output and the V2V converter input; and the negative feedback loop is electrically coupled to the first capacitive sense element node.

The second capacitive sense element node is electrically coupled, via a blocking capacitor (C_{g}), to the V2V converter input, and is further electrically coupled, via a capacitor (“Cₐ”), to ground.

In embodiment(s), since the feedback gain equals 1, VOUT₁=V_{sig}.

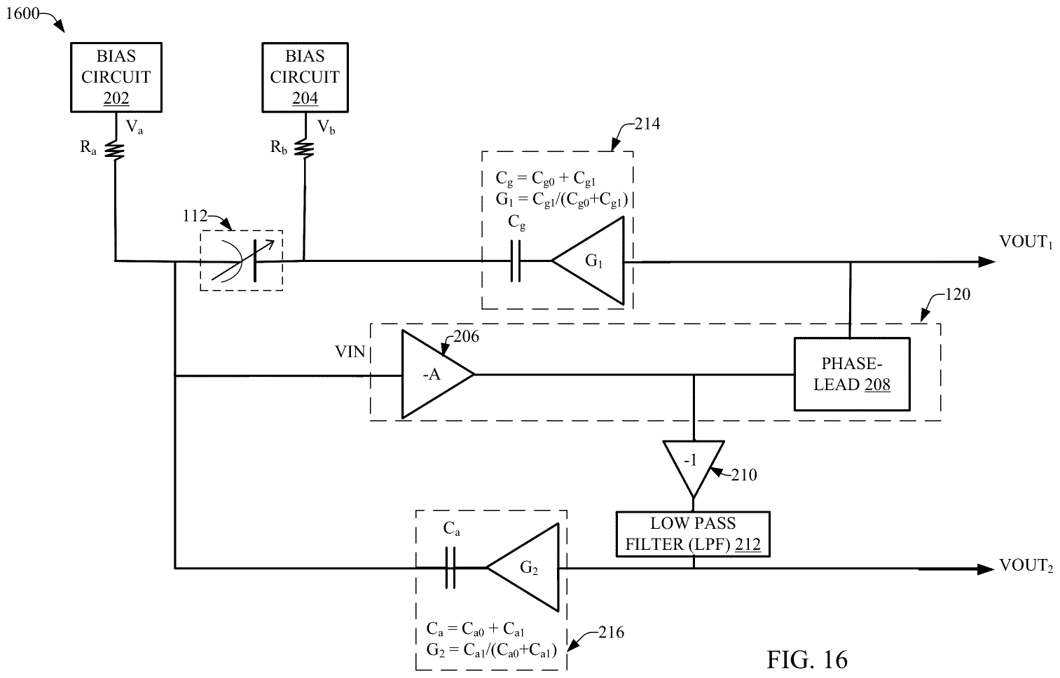

FIG. 16 illustrates a block diagram of a portion of a microphone in which positive and negative feedback voltages are applied to an electromechanical sensor of the microphone utilizing a V2V converter, in which a node of a capacitive sense element of the electromechanical sensor and the negative feedback loop are electrically coupled to an input of the V2V converter to facilitate a reduction in distortion and an improvement in sensitivity of the microphone with respect to sensing changes in acoustic pressure, and in which a phase lead circuit is included in the negative feedback loop, in accordance with various example embodiments.

In this regard, for circuit stability, a gain of the phase-lead circuit (phase-lead 208) boosts a gain of a high frequency response of the negative feedback loop, while LPF 212 reduces a gain of a high frequency response of the positive feedback loop. Therefore, it is advantageous to not have the phase-lead circuit in the positive feedback loop. In a signal frequency band of the electromechanical sensor, a gain of 210 should be equal and opposite to the gain of the phase-lead circuit (phase-lead 208) to provide a differential output, e.g., VOUT₁−VOUT₂.

Reference throughout this specification to “one embodiment,” or “an embodiment,” means that a particular feature, structure, or characteristic described in connection with the embodiment is included in at least one embodiment. Thus, the appearances of the phrase “in one embodiment,” or “in an embodiment,” in various places throughout this specification are not necessarily all referring to the same embodiment. Furthermore, the particular features, structures, or characteristics may be combined in any suitable manner in one or more embodiments.

Furthermore, to the extent that the terms “includes,” “has,” “contains,” and other similar words are used in either the detailed description or the appended claims, such terms are intended to be inclusive—in a manner similar to the term “comprising” as an open transition word—without precluding any additional or other elements. Moreover, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Furthermore, the word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art having the benefit of the instant disclosure.

The above description of illustrated embodiments of the subject disclosure is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. A microphone, comprising:
an electromechanical sensor comprising a capacitive sense element comprising a first capacitive sense element node and a second capacitive sense element node; and
a voltage-to-voltage converter comprising a voltage-to-voltage converter input, a first voltage-to-voltage converter output, and a second voltage-to-voltage converter output, wherein the second capacitive sense element node is electrically coupled to the voltage-to-voltage converter input, wherein the voltage-to-voltage converter forms a negative feedback loop between the first voltage-to-voltage converter output and the voltage-to-voltage converter input, wherein the negative feedback loop is electrically coupled, via a first capacitive coupling, to the first capacitive sense element node, wherein the voltage-to-voltage converter forms, via an amplifier comprising a gain that is greater than one, a positive feedback loop between the second voltage-to-voltage converter output and the voltage-to-voltage converter input, and wherein the positive feedback loop is electrically coupled, via a second capacitive coupling, to the second capacitive sense element node.

2. The microphone of claim 1, wherein at least one of the first capacitive coupling or the second capacitive coupling comprises at least one of:
a capacitive voltage divider,
a resistive voltage divider, or
an amplifier.

3. The microphone of claim 1, wherein an output of the electromechanical sensor comprises a voltage difference between the first voltage-to-voltage converter output and the second voltage-to-voltage converter output and represents acoustic pressure changes that have been sensed by the capacitive sense element.

4. The microphone of claim 3, wherein the positive feedback loop reduces a load capacitance that is electrically coupled to the capacitive sense element.

5. The microphone of claim 4, wherein the positive feedback loop reduces the distortion by electrically coupling a negative capacitance to the capacitive sense element.

6. The microphone of claim 1, wherein the negative feedback loop comprises a voltage divider, and wherein the negative feedback loop modifies, via the voltage divider, a sensitivity of an output of the electromechanical sensor comprising a voltage difference between the first voltage-to-voltage converter output and the second voltage-to-voltage converter output with respect to sensing of acoustic pressure changes that have been sensed by the capacitive sense element.

7. The microphone of claim 6, wherein the negative feedback loop modifies the sensitivity by modifying a circuit gain of the electromechanical sensor.

8. The microphone of claim 3, wherein the first capacitive coupling comprises a first capacitive divider, wherein the second capacitive coupling comprises a second capacitive divider, and wherein a circuit gain of the electromechanical sensor is modified by modifying respective small signal capacitance gains of the first capacitive divider and the second capacitive divider.

9. The microphone of claim 8, wherein the respective small signal capacitance gains are modified by switching respective capacitances of the first capacitive divider and the second capacitive divider to ground.

10. The microphone of claim 1, further comprising a bias circuit that applies a bias voltage to the first capacitive sense element node, wherein the bias voltage sets an operating point of the capacitive sense element to a negative capacitance region.

11. The microphone of claim 1, wherein the voltage-to-voltage converter comprises an inverting amplifier and a phase-lead circuit, wherein the voltage-to-voltage converter input is electrically coupled to an inverting amplifier input of the inverting amplifier, and wherein the negative feedback loop comprises the inverting amplifier and the phase-lead circuit.

12. The microphone of claim 11, wherein the inverting amplifier comprises the phase-lead circuit.

13. The microphone of claim 11, wherein the voltage-to-voltage converter comprises a unity-gain inverting amplifier and a low-pass filter, and wherein the positive feedback loop comprises the unity-gain inverting amplifier and the low-pass filter.

14. The microphone of claim 13, wherein a circuit output corresponding to the phase-lead circuit is electrically coupled to a circuit input corresponding to the unity-gain inverting amplifier.

15. The microphone of claim 13, wherein the unity-gain inverting amplifier comprises the low-pass filter.

16. The microphone of claim 1, wherein a bias voltage is applied, via a bias resistance, to the second capacitive sense element node, and wherein the second capacitive sense element node is electrically coupled, via a blocking capacitor, to the voltage-to-voltage converter input.

17. A microphone, comprising:
an electromechanical sensor comprising a capacitive sense element comprising a first capacitive sense element node and a second capacitive sense element node; and
a voltage-to-voltage converter comprising a voltage-to-voltage converter input and a voltage-to-voltage converter output, wherein the second capacitive sense element node is electrically coupled to the voltage-to-voltage converter input,
wherein the voltage-to-voltage converter forms a negative feedback loop between the voltage-to-voltage converter output and the voltage-to-voltage converter input, wherein the negative feedback loop is electrically coupled, via a capacitive coupling, to the first capacitive sense element node, and wherein the voltage-to-voltage converter output represents acoustic pressure changes that have been sensed by the capacitive sense element.

18. The microphone of claim 17, wherein the capacitive coupling comprises at least one of:
a capacitive voltage divider,
a resistive voltage divider, or
an amplifier.

19. The microphone of claim 17, wherein the negative feedback loop comprises a voltage divider, and wherein the negative feedback loop modifies, via the voltage divider, a sensitivity of the voltage-to-voltage converter output with respect to sensing of the acoustic pressure changes.

20. The microphone of claim 19, wherein the negative feedback loop modifies the sensitivity by modifying a circuit gain of the electromechanical sensor.

21. The microphone of claim 20, further comprising a bias circuit that applies a bias voltage to the first capacitive sense element sense node, wherein the bias voltage sets an operating point of the capacitive sense element to a negative capacitance region.

22. The microphone of claim 17, wherein the voltage-to-voltage converter comprises an inverting amplifier and a phase-lead circuit, wherein the voltage-to-voltage converter input is electrically coupled to an inverting amplifier input of the inverting amplifier, and wherein the negative feedback loop comprises the inverting amplifier and the phase-lead circuit.

23. The microphone of claim 22, wherein the inverting amplifier comprises the phase-lead circuit.

24. The microphone of claim 18, wherein a circuit gain of the electromechanical sensor is modified by modifying a small signal capacitance gain of the capacitive voltage divider.

25. The microphone of claim 24, wherein the small signal capacitance gain is modified by switching capacitances of the capacitive voltage divider to ground.

26. The microphone of claim 17, wherein a bias voltage is applied, via a bias resistance, to the second capacitive sense element node, and wherein the voltage-to-voltage converter input is electrically coupled, via a blocking capacitor, to the second capacitive sense element node.

27. A microphone, comprising:
an electromechanical sensor comprising a capacitive sense element comprising a first capacitive sense element node and a second capacitive sense element node; and
a voltage-to-voltage converter comprising a voltage-to-voltage converter input and a voltage-to-voltage converter output, wherein the second capacitive sense element node is electrically coupled to the voltage-to-voltage converter input, wherein the voltage-to-voltage converter forms a negative feedback loop between the voltage-to-voltage converter output and the voltage-to-voltage converter input, wherein the negative feedback loop is electrically coupled to the first capacitive sense element node, and
wherein the voltage-to-voltage converter output represents acoustic pressure changes that have been sensed by the capacitive sense element.

28. The microphone of claim 27, wherein the voltage-to-voltage converter comprises an inverting amplifier and a phase-lead circuit, wherein the voltage-to-voltage converter input is electrically coupled to an inverting amplifier input of the inverting amplifier, and wherein the negative feedback loop comprises the inverting amplifier and the phase-lead circuit.

29. The microphone of claim 28, wherein the inverting amplifier comprises the phase-lead circuit.

30. The microphone of claim 27, wherein a bias voltage is applied, via a bias resistance, to the second capacitive sense element node, and wherein the voltage-to-voltage converter input is electrically coupled, via a blocking capacitor, to the second capacitive sense element node.

31. A microphone, comprising:
an electromechanical sensor comprising a capacitive sense element comprising a first capacitive sense element node and a second capacitive sense element node;
a bias resistance that electrically couples a bias voltage to the second capacitive sense element node; and
a voltage-to-voltage converter comprising a voltage-to-voltage converter input, a first voltage-to-voltage converter output, and a second voltage-to-voltage converter output, wherein the second capacitive sense element node is electrically coupled, via a blocking capacitor, to the voltage-to-voltage converter input, wherein the voltage-to-voltage converter forms a negative feedback loop between the first voltage-to-voltage converter output and the voltage-to-voltage converter input, wherein the negative feedback loop is electrically coupled to the first capacitive sense element node, wherein the voltage-to-voltage converter forms, via an amplifier comprising a gain that is greater than one, a positive feedback loop between the second voltage-to-voltage converter output and the voltage-to-voltage converter input, and wherein the positive feedback loop is electrically coupled, via a capacitive coupling, to the second capacitive sense element node.

32. The microphone of claim 31, wherein the capacitive coupling comprises at least one of:
a capacitive voltage divider,
a resistive voltage divider, or
an amplifier.

33. The microphone of claim 31, wherein an output of the electromechanical sensor comprises a voltage difference between the first voltage-to-voltage converter output and the second voltage-to-voltage converter output and represents acoustic pressure changes that have been sensed by the capacitive sense element.

34. The microphone of claim 33, wherein the positive feedback loop reduces a load capacitance of the output of the electromechanical sensor.

35. The microphone of claim 34, wherein the positive feedback loop reduces the signal distortion by electrically coupling a negative capacitance to the capacitive sense element.

36. The microphone of claim 31, wherein the voltage-to-voltage converter comprises an inverting amplifier and a phase-lead circuit, wherein the voltage-to-voltage converter input is electrically coupled to an inverting amplifier input of the inverting amplifier, and wherein the negative feedback loop comprises the inverting amplifier and the phase-lead circuit.

37. The microphone of claim 36, wherein the inverting amplifier comprises the phase-lead circuit.

38. The microphone of claim 36, wherein the voltage-to-voltage converter comprises a unity-gain inverting amplifier and a low-pass filter, wherein a circuit output corresponding to the phase-lead circuit is electrically coupled to a circuit input corresponding to the unity-gain inverting amplifier, and wherein the positive feedback loop comprises the unity-gain inverting amplifier and the low-pass filter.

39. The microphone of claim 38, wherein a circuit output corresponding to the phase-lead circuit is electrically coupled to a circuit input corresponding to the unity-gain inverting amplifier.

40. The microphone of claim 38, wherein the unity-gain inverting amplifier comprises the low-pass filter.
